(19) United States
(12) Patent Application Publication
(10) Pub. No.: US 2026/0304695 A1
(43) Pub. Date: Oct. 1, 2026

(54) MULTIMODE IMMERSION COOLING USING COOLANT WITH NO FLASH POINT, HIGH HEAT OF VAPORIZATION AND HIGH THERMAL CONDUCTIVITY

(71) Applicant: Nano and Advanced Materials Institute Limited, Hong Kong (HK)

(72) Inventors: Chi Ho KWOK, Hong Kong (HK); Manami KAWAKAMI, Hong Kong (HK); Wai Chung LI, Hong Kong (HK); Tsz Yu HUNG, Hong Kong (HK); Yanhui WANG, Hong Kong (HK); Li FU, Hong Kong (HK)

(21) Appl. No.: 19/091,788

(22) Filed: Mar. 26, 2025

(51) Int. Cl. H05K 7/20; C09K 5/04

(52) U.S. Cl. CPC H05K 7/203; C09K 5/048; H05K 7/20236; H05K 7/20272; H05K 7/20281; H05K 7/20318; H05K 7/20327; H05K 7/20381

(57) ABSTRACT

A multimode immersion cooling system is provided herewith, wherein the system can operate in a two-phase immersion cooling mode or, upon demand, simultaneously a two-phase immersion cooling mode and a one-phase immersion cooling mode. Also provided herewith is a thermal transfer fluid specifically designed to act simultaneously as a two-phase immersion coolant and a one-phase immersion coolant, with excellent thermal stability, good dielectric and mechanical properties, and is synthesizable in relatively environmentally-friendly and simple processes.

### FIELD OF THE INVENTION

The present invention relates to multimode immersion cooling. More particularly, a multimode immersion cooling system integrating two-phase immersion cooling and one-phase immersion cooling, and a specifically formulated coolant is provided herewith.

### BACKGROUND

Electronic components generate intense heat during operation. As the computing powers of modern electronics such as data centers, power electronics, electric vehicle batteries and high-performance computing (HPC) systems improve, the amount of heat generated from the electronic components is also inevitably large.

However, excess heat poses multiple risks that require immediate attention. Not only would excess heat in electronic components cause thermal throttling, a phenomenon in which the processing unit automatically starts sacrificing performance to maintain or reduce temperature once the system reaches critical temperatures, but if the temperature remains uncontained, system failure may occur.

Traditionally, air conditioning and air-based heat removal systems have been used. However, these systems often consume considerable power usage, and may take up a lot of space, thus making the system less desirable in terms of cost-effectiveness. Accordingly, immersion cooling systems were developed, which drastically cuts the energy consumption as compared to air conditioning or air-based cooling systems.

Immersion cooling systems are further categorized into one-phase and two-phase systems. One-phase immersion cooling systems use a cooling fluid to remove the heat, while the fluid remains in liquid form. The heated fluid is usually circulated to an external cooling facility to cool down and be recirculated back to the heat removal tank. On the other hand, in two-phase immersion cooling systems, the cooling fluid vaporizes upon heat absorption, and condenses back into liquid form. This mechanism further leverages the latent heat of vaporization of the fluid, thereby able to absorb a greater amount of heat.

A variety of cooling fluids have been developed, including but not limited to industrial and commercial refrigerants, mineral oils, silicone-based fluids and other synthetic dielectric fluids. However, none of these fluids have been able to balance between a multitude of factors, including good heat removal capacity, low cost, environmentally friendly or non-toxic synthesis and desirable dielectric properties. Additionally, generally the volume of cooling fluids needed to cool down electronic equipment is high, therefore the relatively viscous and dense cooling fluids have a further drawback in lack of convenience due to difficult transportation.

In particular, existing cooling fluids are specifically designed for use in either one-phase or two-phase immersion cooling system, but none with common applicability to both types of systems.

Thus, there is a need in the art for a cooling fluid that combines the advantages of environmentally-friendly and less toxic synthesis, reasonable cost, good thermal stability, good dielectric performances and lower density. The present invention addresses this need.

In addition, the present invention presents a multimode immersion cooling system, integrating a two-phase immersion cooling operation mode and a one-phase immersion cooling operation mode which can be simultaneously operated, thereby enabling more efficient heat removal and greater heat removal capacity. The multimode immersion cooling system is further characterized by the use of a single cooling fluid, i.e. the cooling fluid with the specifically designed compound of the present invention.

### SUMMARY OF THE INVENTION

The present invention provides a multimode immersion cooling system, which can operate in a two-phase immersion cooling mode and, upon a higher demand for cooling, a single-phase immersion cooling mode can be simultaneously operated to facilitate the cooling process.

Specifically, the multimode immersion cooling system comprises a fluid-retaining container having space for accommodating an electronic device, a single thermal transfer fluid positioned in the container such that the electronic device is at least partially in contact with the thermal transfer fluid, the thermal transfer fluid remaining in a liquid phase in a first single-phase immersion cooling mode and vaporizing when the thermal transfer fluid temperature reaches its boiling point in a second two-phase immersion cooling mode, a first two-phase mode heat-removal sub-system communicating with the fluid-retaining container, a second single-phase mode heat removal sub-system communicating with the fluid-retaining container, the second heat removal sub-system communicating with the fluid-retaining container, and a controller for determining whether the multimode immersion cooling system operates only in the first two-phase mode, or whether the multimode immersion cooling system operates in the first two-phase mode and the second single-phase mode.

The first two-phase mode heat-removal sub-system comprises a condenser for contacting vapor from vaporized thermal transfer fluid such that vapor from vaporized thermal transfer fluid that contacts the condenser during the first, two-phase immersion cooling mode. Meanwhile, the second single-phase mode heat removal sub-system comprises one or more pumps and fluid-removal conduits communicating with the fluid-retaining container to remove heated thermal transfer fluid from the thermal transfer fluid positioned in the fluid-retaining container during the second single-phase immersion cooling mode, a heat exchanger for extracting thermal energy from the heated thermal transfer fluid to form cooled thermal transfer fluid, and one or more pumps and fluid-returning conduits communicating with the fluid-retaining container to return the cooled thermal transfer fluid to the fluid-retaining container.

The multimode immersion cooling system employs a thermal transfer fluid of formula (I).

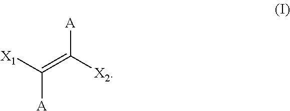

In the above compound of formula (I), X₁ and X₂ are independently selected from halogen, linear or branched partially- or fully-halogenated C₁-C₆ alkyl groups or linear or branched partially- or fully-halogenated C₁-C₆ alkenyl groups, or X₁ and X₂ are connected to form a C₅-C₆ partially- or fully-halogenated cyclic structure, and A is selected from hydrogen, halogen, unhalogenated methyl group or halogenated methyl group. Specifically, the degree of fluorination of the compound of formula (I) is no less than 75%.

In one embodiment of the present invention, the boiling point of the thermal transfer fluid ranges from 50° C. to 140° C.

In another embodiment, the thermal transfer fluid is non-flammable and possess no flash point.

In a further embodiment, the thermal transfer fluid has a dielectric constant of no higher than 2.0 at a frequency of 20-40 GHz.

In yet another embodiment, the thermal transfer fluid has a heat of vaporization of 100-150 kJ/kg.

In yet another embodiment, the thermal transfer fluid has a specific heat capacity of no less than 1000 J/kgK.

In another embodiment, the thermal transfer fluid has a breakdown voltage of no lower than 50 kV/0.1 inch.

In another embodiment, the controller circulates a cooling fluid to the condenser during the operation of the first two-phase mode heat-removal sub-system.

In yet another embodiment, the second single-phase mode heat removal sub-system includes a first conduit for transporting heated thermal transfer fluid from the fluid-retaining container.

The second single-phase heat removal sub-system may include a pump for transporting the heated thermal transfer fluid in the first conduit.

In another embodiment, the first conduit contacts one or more second conduits having one or more cooling fluids circulating through the one or more second conduits.

In a further embodiment, the cooled thermal transfer fluid is returned to the fluid-retaining container via the first conduit or via one or more second conduits.

In a further embodiment, the system further comprises a fluid injector having one more fluid injector outlets to distribute cooled thermal transfer fluid directly adjacent to one or more targeted heat-generating components of an electronic device.

In other embodiment, the condenser of the first two-phase mode heat-removal sub-system includes one or more coils positioned in the fluid-retaining container, the one or more coils having coil cooling fluid circulating therethrough.

In a further embodiment, the circulating cooling fluid extracts heat from the thermal transfer fluid vapor to condense the thermal transfer fluid.

The circulating cooling fluid may transfer the extracted heat from the thermal transfer fluid to the atmosphere by a cooling tower.

### BRIEF DESCRIPTION OF THE DRAWINGS

FIG. 1 shows exemplary species of the compounds of the present invention, specifically designed as a major component of the thermal transfer fluid for the multimode immersion cooling system of the present invention.

FIG. 2 is a schematic illustration of the two-phase heat-removal sub-system of the multimode immersion cooling system of the present invention.

FIG. 3 is a schematic illustration of an exemplary setup of the multimode immersion cooling system of the present invention.

FIG. 4 shows the tabulation of the physical properties of the exemplary species of the compounds of the present invention in FIG. 1.

### DETAILED DESCRIPTION

As used in this specification herein, the terms “cooling fluids”, “coolants” and “thermal transfer fluids” are used interchangeably.

As described above, while multiple cooling fluids have been developed, they are generally designed for use in either one-phase immersion cooling system or two-phase immersion cooling system, and each have its own shortcomings, as discussed below.

### 1. One-Phase Immersion Coolants

One-phase coolants refer to coolants that absorb heat without undergoing phase change, and remains in liquid phase throughout the entire cooling process.

To start with, mineral oils, which are dielectric oils derived from petroleum, are common one-phase coolants. They are readily available with reasonable costs, are safe for electronics due to their non-conductivity and have good heat capacity. However, they have relatively low flash points which makes them thermally less stable upon high heat, and may become viscous as they degrade over time, and may also leave residue on electronic components, thereby hampering the performances of the electronic components and cause damage.

In response, synthetic dielectric hydrocarbons or esters are designed for insulation and cooling. While having higher thermal stability, less degradation and lower viscosity than mineral oils, their costs are significantly higher. Also, the existence of flash points of some variants imply that flammability is still a safety concern that needs to be rectified.

Non-petroleum non-conductive silicone-based fluids, for example polydimethylsiloxane (PDMS) fluids, are also used as a one-phase coolant. It is known to have considerable thermal stability, is non-flammable and is non-toxic. However, it is also one of the higher cost options compared to other coolants, and it also has a relatively low heat capacity, therefore its heat removal efficiency is sub-optimal.

### 2. Two-Phase Coolants

Compared to one-phase coolants, two-phase coolants absorb heat and boil into vapor before condensing back into their liquid form. This allows the cooling system to leverage its cooling capacity with the latent heat of vaporization of the coolants, but in turn further requiring the coolants to have low boiling points and considerable dielectric properties.

Pre-existing fluorocarbon-based fluids are engineered with precisely selected boiling points to enable the phase changes as described. They are non-flammable and chemically stable; however, the costs of engineering these fluids are extremely high. The synthesis of these fluorocarbon-based fluids is also highly environmentally-unfriendly.

Meanwhile, certain industrial and commercial refrigerants are also being adapted for two-phase immersion cooling applications. They are readily available, and due to its wide application in HVAC industries, the properties of these refrigerants are thoroughly studied and well understood. However, some refrigerants have flammability concerns, which render them undesirable for use due to lack of safety. In addition, some refrigerants are regulated due to their environmental impact, for example ozone depletion.

As discussed above, there is a lack of coolant which is able to solve all limitations, i.e. cost, environmental impact, flammability and viscosity, all at once. The coolant in the present invention, as described in the sections below, is designed to have considerable properties across multiple safety and performance parameters, the syntheses of which are also non-toxic and environmentally friendly.

There are a multitude of parameters that must be taken into consideration when engineering the coolant of the present invention for immersion cooling. Firstly, the boiling point of the fluid must be low enough such that phase change is possible without causing overheating, while not too low to prevent excessive evaporation losses and difficult vapor management. As such, the coolants of the present invention are designed to range from 40° C. to 150° C., a range that allows effective heat removal from the electronic components without causing overheating.

The coolant fluid must have a breakdown voltage high enough to prevent electrical breakdown, ensuring that the fluid safely insulates the electronic components by the prevention of arcing and short circuit risks. The coolants of the present invention are tested to have breakdown voltages of no lower than 50 kV per 0.1 inch to ensure safe insulation.

It is also crucial to control the dielectric constant of the coolant fluid to be high enough to maintain reasonable capacitance while not at a level too high to cause electrical losses and signal distortion. As such, the coolants of the present invention are engineered to have average dielectric constants controlled within a range lower than 3.0 at a frequence of 20-40 GHz.

A low dielectric loss is also of utmost importance to minimize energy dissipation in the form of heat. The dielectric losses of most of the coolant species of the present invention are controlled to be in the 10³ level or lower.

A high heat of vaporization is the key to an efficient immersion coolant as it allows better heat absorption pre fixed volume of fluid; but an excessively high heat of vaporization is also not ideal as it in turn requires excessive energy for phase transition. The coolants in the present invention are precisely engineered to have heats of vaporization in the range of 100-150 kJ/kg, allowing efficient heat absorption while still facilitating phase transition for two-phase cooling.

The present invention uses a coolant compound that enables multimode immersion cooling and satisfies the above criteria. The coolant compound of the present invention has a general structure of Formula (I) as below:

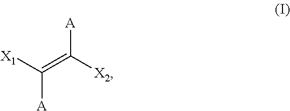

where X₁ and X₂ are independently selected from halogen, linear or branched partially- or fully-halogenated C₁-C₆ alkyl groups or linear or branched partially- or fully-halogenated C₁-C₆ alkenyl groups, or X₁ and X₂ are connected to form a C₅-C₆ partially- or fully-halogenated cyclic structure; and A is selected from hydrogen, halogen, unhalogenated methyl group or halogenated methyl group. It is also crucial that this coolant compound has a degree of fluorination of no less than 75%.

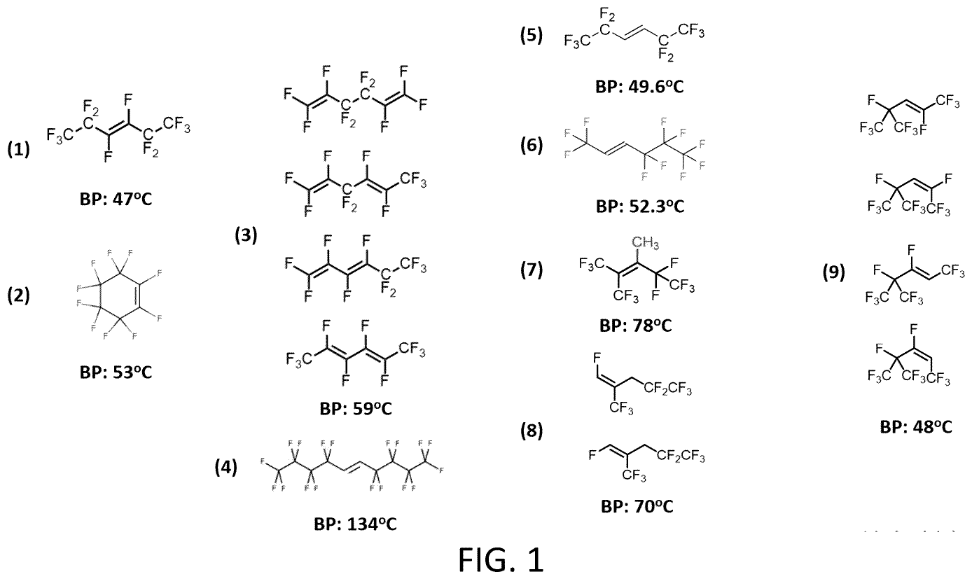

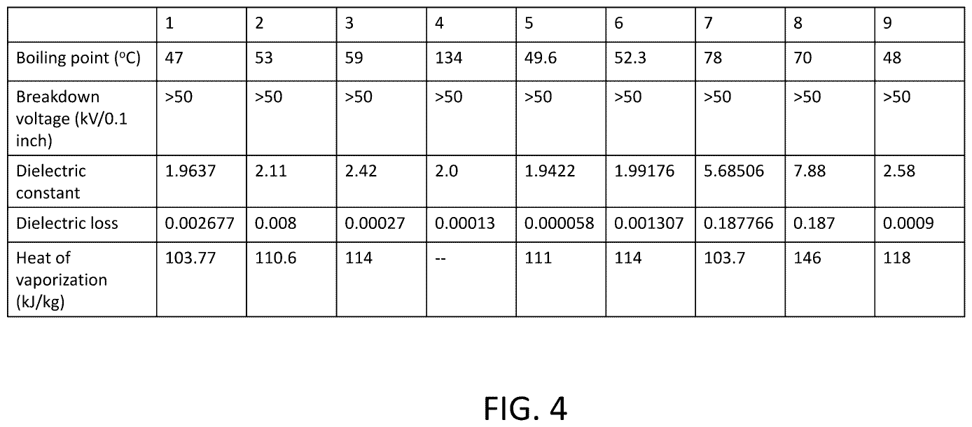

FIG. 4 tabulates the various properties of the 9 exemplary coolant compounds as shown in FIG. 1 and synthesized according to the procedures described in Examples below. It is worth noting that Compounds 3, 8 and 9 are isomers that are synthesized simultaneously through the syntheses procedures as described below in the Examples.

There are a multitude of parameters that must be taken into consideration when engineering a coolant for immersion cooling. Firstly, the boiling point of the fluid must be low enough such that phase change is possible without causing overheating, while not too low to prevent excessive evaporation losses and difficult vapor management. As such, the coolants of the present invention are designed to range from 40° C. to 150° C., a range that allows effective heat removal from the electronic components without causing overheating.

The coolant fluid must have a breakdown voltage high enough to prevent electrical breakdown, ensuring that the fluid safely insulates the electronic components by the prevention of arcing and short circuit risks. The coolants of the present invention are tested to have breakdown voltages of no lower than 50 kV per 0.1 inch to ensure safe insulation.

It is also crucial to control the dielectric constant of the coolant fluid to be high enough to maintain reasonable capacitance while not at a level too high to cause electrical losses and signal distortion. As such, the coolants of the present invention are engineered to have average dielectric constants controlled within a range lower than 2.0 at a frequence of 20-40 GHz. This is particularly crucial for high-speed data transmission, for example PCIe 5.0, which are highly sensitive to material properties, to minimize signal loss and attenuation and maintaining low latency.

A low dielectric loss is also of utmost importance to minimize energy dissipation in the form of heat. The dielectric losses of most of the coolant species of the present invention are controlled to be in the 10-3 level or lower.

A high heat of vaporization is the key to an efficient immersion coolant as it allows better heat absorption pre fixed volume of fluid; but an excessively high heat of vaporization is also not ideal as it in turn requires excessive energy for phase transition. The coolants in the present invention are precisely engineered to have heats of vaporization in the range of 100-150 kJ/kg, allowing efficient heat absorption while still facilitating phase transition for two-phase cooling.

It is also worth mentioning that, despite not having been tabulated in FIG. 4, all species of coolants in the present invention also have specific heat capacities of at least 1000 J/kgK which, coupled with the specifically engineered range of heat of vaporization, makes the coolants of the present invention simultaneously efficient in both two-phase immersion cooling and one-phase immersion cooling.

In addition, essentially, all species of coolants in the present invention have no flash points, meaning that all these coolant species are strictly non-flammable, thereby proving their safety for use as immersion coolants.

Not only are the coolant species of the present invention thermally stable and exhibiting excellent functionality, they are also engineered to be of lower density and viscosity ranges, particularly a density ranging from 1100 to 1800 kg/m³, and a viscosity ranging from 0.4 to 1.0 cSt. The low viscosity ensures enhanced flow rate and thus prevents localized overheating; while the low density and hence lighter weight makes the system more efficient and mobile.

Synthesis procedures of exemplary compounds having the structure of Formula I is set forth in the Examples below.

### EXAMPLES

### A. Compound Synthesis

### Synthesis of Compound 1:

To a 500 mL dry single neck round bottom flask, NaOH (10.4 g, 0.95 eq) and EtOH (100 mL) are added. Then, tridecafluoroheptanoic acid (100 g, 1.0 eq) in 100 mL EtOH solution is added dropwise. As this reduction process is exothermic, the reagent should be added slowly to maintain the temperature of the reaction mixture low. After being stirred at room temperature for overnight, the reaction mixture is filtered and the solid was washed with 500 mL Et₂O. The colorless solid is then dried under vacuum pump.

The tridecafluoroheptanoic sodium salt is transferred to a 1000 mL dry single neck round bottom flask, heated and distilled at 320° C. Yellow liquids (60.27 g) are collected at 80° C. The same distillation procedures are repeated one more time to achieve colorless oil (52 g, 62%).

To a 100 mL dry single neck round bottom flask, the above-mentioned colorless oil (30 g, 1.0 eq), CsF (0.84 g, 0.05 eq) and 6 mL diglyme are added. The mixture is heated at 100° C. under N₂ atmosphere by using 10° C. condenser to prevent loss of low boiling point products. After 18 h, 20 mL of distilled water is added to the reaction mixture, and the bottom organic layer is separated using a 100 mL separation funnel. The organic layer is further washed with distilled water (20 mL) twice to remove diglyme. After drying over sodium sulfate and filtered, crude yellow oil (13.9 g, 46%) is transferred to a 50 mL dry single neck round bottom flask and distilled with a distillation column to achieve 85% purity. Colorless liquids (9.4 g, 31% yield) are collected at 46-48° C.

¹⁹F-NMR (58 MHz) δ −70 (m, 0.9 F), −84 (m, 1 F), −86 (S, 6F), −123 (d, 4F), −156 (m, 2F) ppm.

### Synthesis of Compound 2:

To a 500-mL round-bottom flask equipped with a magnetic stirring bar coated with Teflon, 1,6-diiodoperfluorohexane (10 g, 0.01806 mol) and 150 ml tetrahydrofuran are added. Then, 1M EtMgBr in THE (39 mL, 2.2 eq., 0.03973 mol) is added at 0° C. to the RB-flask in a single portion. The mixture is stirred at 0° C. for 1 hour. After warming to room temperature, the mixture stirred for 2 hours. The resulting mixture is distilled to give the desired compounds (0.473 g, 0.001806 mol, 10% percentage yield).

¹⁹F-NMR (470 MHz, CDCl₃) δ −118.92 ppm~−118.93 ppm (4F, m), −133.82 (4F, s), −151.29~−151.37 (2F, m) ppm

### Synthesis of Isomeric Compounds 3:

To a 500 mL dry single neck round bottom flask, NaOH (25.0 g, 1.95 eq) and EtOH (150 mL) are added. Then, dodecafluorosuberic acid (125 g, 1.0 eq) in 150 mL EtOH solution was added dropwise. As this reduction process is exothermic, the reagent should be added slowly to maintain the temperature of the reaction mixture low. After being stirred at room temperature for overnight, the solvent is removed using rotary evaporation. The mixture is filtered and the solid is washed with 500 mL Et₂O. Then the colorless solid is dried in oven (100° C., 12 h) and vacuum pump.

The dodecafluorosuberic sodium salt is transferred to a 1000 mL dry single neck round bottom flask, heated and distilled at 320° C. Yellow liquids are collected at 59° C. 50 mL of distilled water is added to the crude product, and the bottom organic layer is separated using a 250 mL separation funnel. The organic layer is further washed with distilled water (50 mL) twice to remove acid. After drying over sodium sulfate and filtered, crude yellow oil is transferred to a 250 mL dry single neck round bottom flask and distilled with a distillation column to achieve colorless liquid (37.0 g, 44% yield).

¹⁹F NMR (470 MHz, CDCl₃) δ−87 (m, 1.2 F), −88 (m, 2F), −105 (m, 2F), −109 (m, 0.5F), −118 (m, 4F), −188 (m, 2F) ppm.

### Synthesis of Compound 4:

In a 250 mL Schlenk tube equipped with a Teflon stirrer, 60 g (0.244 mol) of 1H,1H,2H-perfluoro-1-hexene (CAS 19430-93-4) and 108 g (0.312 mol) of nonafluoro-4-iodo Butane (CAS 423-39-2) and 3.6 g (0.024 mol) of di-tert-butyl peroxide (CAS 110-05-4) are added. Schlenk tube is evacuated and purged with nitrogen gas for three times, and then sealed. The sealed Schlenk tube is stirred and heated to 130° C. for 18 hours. After the Schlenk tube is cooled to room temperature, the reaction mixture is poured out from the Schlenk tube and used directly in the next step without further purification.

In a 250 mL two-neck round-bottom flask equipped with a Teflon stirrer, two dropping funnels each containing 130 ml of 2M potassium hydroxide (0.2684 mol) (CAS: 1310-58-3) in methanol and 100 g of N2 precursor are inserted. Then, liquids from the two dropping funnels are added dropwise into the round-bottomed flask together at room temperature. The resulting mixture is stirred for 3 hours. The reaction is quenched by adding saturated ammonium chloride solution. The liquid at the bottom is separated and then purified by distillation to obtain the desired compounds (b.p. 134° C.). (56 g, 0.122 mol, 2-step reaction yield: 50%.)

¹H-NMR (500 MHz, CDCl₃) δ 6.44-6.53 (m) ppm

¹⁹F-NMR (470 MHz, CDCl₃) δ −81.39 ppm~−81.35 (6F, m), −114.45 ppm~−114.46 ppm (4F, m), −124.57~−124.52 (4F, m), −126.07~−126.11 (4F, m)

### Synthesis of Compound 5:

In a 50 mL two-neck round-bottom flask equipped with a Teflon stirrer, two dropping funnels each containing 10 g iodoprecursor (393.98 g mol⁻¹, 0.02538 mol) and 15 mL 2M potassium hydroxide (1.1 eq., 0.0279 mol) are inserted. Then, liquids from the two dropping funnels are added dropwise into the round-bottomed flask together at room temperature. The resulting mixture is stirred for 3 hours. The reaction is quenched by adding saturated ammonium chloride solution. The liquid at the bottom is separated and then purified by distillation to obtain the compounds (b.p. 48-50° C.). (3.35 g, 0.01269 mol, 50% percentage yield).

¹H-NMR (500 MHz, CDCl₃) δ 6.42-6.51 (m) ppm

¹⁹F-NMR (470 MHz, CDCl₃) δ −86.48 (6F, s), −119.25~−119.26 (4F, m) ppm

### Synthesis of Compound 6:

To a 200 mL PFTE container, heptafluoropropyl iodide (17.6 g, 1.8 eq), 2-bromo-3,3,3-trifluoro-1-propene (5.8 g, 1.0 eq), copper mesh (21.0 g, 10 eq) and dry dimethylformamide (40 mL) are added. The PFTE container is placed into an autoclave and closed tightly, then the crude solution is heated at 120° C. for 18 h. The reaction mixture is cooled down to room temperature and distilled with distillation column to remove the solvent. Colorless liquids (2.1 g, 21% yield) are collected at 52° C.

¹H-NMR (60 MHz, CDCl₃) δ 5.8 (m, 2H) ppm

¹⁹F-NMR (56 MHz, CDCl₃) δ−68, −82, −115, −129 ppm

### Synthesis of Compound 7:

To a 1000 mL dry single neck round bottom flask, perfluoro(4-methylpent-2-ene) (320 g, 1.0 eq), cesium fluoride (24.3 g, 0.15 eq), sulfolane (38.4 g, 0.30 eq) and dry diglyme (200 mL) are added. The reaction mixture was stirred at 70° C. with a reflux condenser for 1 h. After confirming the completion of the reaction with ¹⁹F-NMR, the reflux condenser is replaced with a distillation column, and the reaction mixture is heated at 70° C. Perfluoro(1-methylpent-1-ene) is collected at 48-52° C. as colorless liquids (260 g, 81% yield).

To a 100 mL dry two neck round bottom flask, perfluoro(2-methylpent-2-ene) (20 g, 1.0 eq) and dry diethyl ether (30 mL) are added under nitrogen. The reaction mixture is cooled down to 0° C. in an ice bath, then methyl magnesium bromide solution (2M in diethyl ether, 33 mL, 1.0 eq) is added dropwise over 40 min using a dropping funnel. The reaction mixture is further stirred for 30 min at the same temperature, then quenched with distilled water slowly. The organic layer is separated using a 100 mL separation funnel. The crude solution is heated at 50° C. and distilled with distillation column to remove the solvent. Then the crude Methyl-substituted D2 is heated at 110° C. and distilled with distillation column. Colorless liquids (12.5 g, 63% yield) are collected at 72-78° C.

¹⁹F-NMR (470 MHz, CDCl₃) δ−67, −84, −117 ppm.

### Synthesis of Isomeric Compounds 8:

To a 1000 mL dry single neck round bottom flask, perfluoro(4-methylpent-2-ene) (320 g, 1.0 eq), cesium fluoride (24.3 g, 0.15 eq), sulfolane (38.4 g, 0.30 eq) and dry diglyme (200 mL) are added. The reaction mixture is stirred at 70° C. with a reflux condenser for 1 h. After confirming the completion of the reaction with ¹⁹F-NMR, the reflux condenser is replaced with a distillation column, and the reaction mixture is heated at 70° C. Perfluoro(1-methylpent-1-ene) is collected at 48-52° C. as colorless liquids (260 g, 81% yield).

To a 1000 mL dry single neck round bottom flask, lithium aluminum hydride (3.8 g, 1.0 eq) and dry diethyl ether (230 mL) are added under nitrogen. The reaction mixture is cooled down to −85° C. using ethyl acetate and liquid nitrogen bath, then perfluoro(2-methylpent-2-ene) (30 g, 1.0 eq) in dry diethyl ether (100 mL) is added dropwise over 1 h using a dropping funnel. As this reduction process is exothermic, slow addition was required to maintain the low temperature. The reaction mixture is further stirred for 1 h at the same temperature, then quenched with distilled water slowly. The resultant grey solid is removed through celite filtration and washed with diethyl ether (50 mL). The crude solution is heated at 75° C. and distilled with distillation column to remove the solvent. Then the crude compounds is heated at 110° C. and distilled with distillation column to remove partially reduced byproducts. Finally, colorless liquids (5.8 g, 24% yield) are collected at 70° C.

¹H-NMR (60 MHz, CDCl₃) δ 7.4 (0.77H, m), 6.9 (0.23H, m), 3.0 (2H, m) ppm.

¹⁹F-NMR (56 MHz, CDCl₃) δ −59, −63, −83, −84, −114, −116 ppm

### Synthesis of Isomeric Compounds 9:

To a 1000 mL dry single neck round bottom flask, perfluoro(4-methylpent-2-ene) (83 g, 1.0 eq) and dry dimethylacetamide (500 mL) are added. Then, sodium borohydride (11.3 g, 1.2 eq) is added at 0° C. portion by portion over 1 h. As this reduction process is exothermic, the reagent should be added slowly to maintain the temperature of the reaction mixture low. After being stirred at 0° C. for 1 h, 500 mL of distilled water is added to the reaction mixture, and the bottom organic layer is separated using a 1000 mL separation funnel. The organic layer is further washed with distilled water (100 mL) twice to remove dimethylacetamide. After drying over sodium sulfate and filtered, crude compounds are transferred to a 50 mL dry single neck round bottom flask and distilled with a distillation column at 95° C. to remove over-reduced compounds. The same fractional distillation is repeated three times to achieve 95% purity. Colorless liquids (31.0 g, 44% yield) are collected at 46-48° C.

¹H-NMR (500 MHz, CDCl₃) δ 6.25 (0.07H, m), 6.05 (0.04H, m), 5.90 (0.47H, m), 5.68 (0.19H, m), 4.25 (0.04H, m), 4.10 (0.19H, m) ppm

¹⁹F-NMR (470 MHz, CDCl₃) δ −54, −60, −65, −68, −73, −75, −76, −109, −123, −183 ppm

The syntheses routes above for the respective exemplary coolant compounds for the present invention involve less toxic substances and procedures that may cause environmental hazards. Also, all these syntheses routes do not involve gaseous starting materials and multiple steps, therefore the syntheses of these materials are comparatively simple, environmentally friendly (in particular, lower global warming potential (GWP) and more industrially scalable.

### B. Multimode Immersion Cooling System

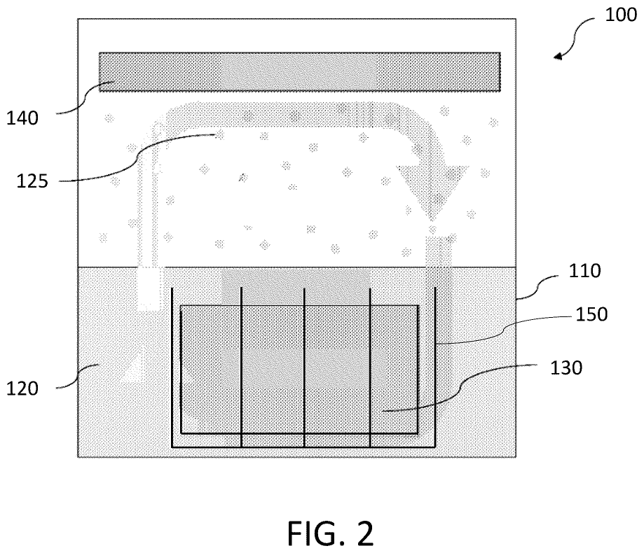

The central part of the multimode immersion cooling system is a two-phase immersion cooling system 100, an illustrative depiction of which is seen in FIG. 2, where the thermal transfer fluid in the two-phase immersion cooling system 100 is selected from a compound of Formula (I), for example, at least one of Compounds 1-9.

The two-phase immersion cooling system 100 comprises a fluid-retaining container 110 for the cooling of the electronic device 130 to be cooled, a single thermal transfer fluid 120 which is the coolant as described in Example 1, the heat exchanger 140 which is a condenser for contacting vapor 125 from vaporized thermal transfer fluid such that vapor from vaporized thermal transfer fluid that contacts the condenser and condenses back to its liquid phase 120.

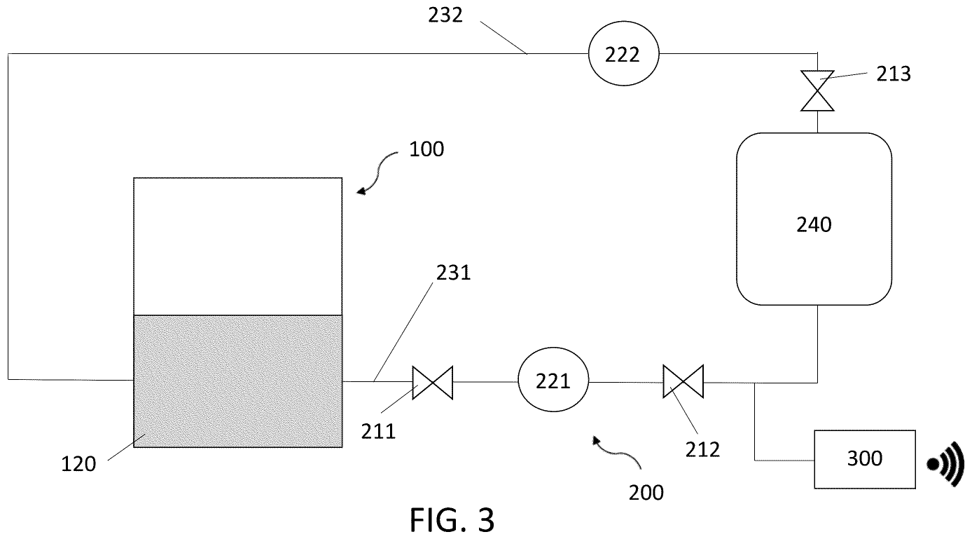

Referring to the FIG. 3, the two-phase immersion cooling system 100 is also connected to the one-phase immersion cooling system 200. The fluid-retaining container 110 of the two-phase immersion cooling system 100 is also externally connected to valves 211, 212 and pump 221 through conduit 231 to an external cooling facility 240. The externally cooling facility 240 is then connected back to the fluid-retaining container 110 through valve 213, pump 222 and conduit 232.

The opening or closure of valves 211, 212 and 213, pumps 221 and 222, and the operation of the cooling facility 240 are controlled by the controller 300.

While the main cooling task is carried out through two-phase immersion cooling in the two-phase immersion cooling system 100, but in cases where a higher heat removal capacity is needed and, as such, quicker cooling is needed, the one-phase immersion cooling system 200 can be put into operation through controller 300, in which the thermal transfer fluid is the same as the two-phase immersion cooling system, i.e. a fluid of at least a compound of Formula (I), for example, one of Compounds 1-9. The valves 211 and 212 can be opened and pump 221 can be operated such that the heated thermal transfer fluid 120 can flow through conduit 231 to the external cooling facility 240, which can be, for example, a cooling tower. Once the cooling is complete, the cooled thermal transfer fluid can be transferred back from the external cooling facility 240 with the operation of valve 213 and pump 222 back to the fluid-retaining container 110 via conduit 232.

The condenser 140 have a variety of configurations, including serpentine coils, bundles of straight tubes, shell and tube, plates with fluid channels, microchannels, finned coils and cylindrical coils, within which a cooling fluid runs through to maintain a low temperature of the exterior of the condenser in comparison to the thermal transfer fluid 120 to facilitate the condensation of vaporized thermal transfer fluid 125. The cooling fluid running through the condenser 140 can be selected from a variety of fluids including but not limited to water, industrially available refrigerants. Optionally, the fluid can be externally chilled or connected to the external cooling facility 240 through an additional conduit loop for cooling.

Several embodiments of the present disclosure and features of details are briefly described above. The embodiments described in the present disclosure may be easily used as a basis for designing or modifying other processes and structures for realizing the same or similar objectives and/or obtaining the same or similar advantages introduced in the embodiments of the present disclosure. Such equivalent construction does not depart from the spirit and scope of the present disclosure, and various variations, replacements, and modifications can be made without departing from the spirit and scope of the present disclosure.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

1. A multimode immersion cooling system for a first two-phase immersion cooling mode and a second single-phase immersion cooling mode comprising:
a fluid-retaining container having space for accommodating an electronic device;
a single thermal transfer fluid positioned in the container such that the electronic device is at least partially in contact with the thermal transfer fluid, the thermal transfer fluid remaining in a liquid phase in a first single-phase immersion cooling mode and vaporizing when the thermal transfer fluid temperature reaches its boiling point in a second two-phase immersion cooling mode;
a first two-phase mode heat-removal sub-system communicating with the fluid-retaining container including:
a condenser for contacting vapor from vaporized thermal transfer fluid such that vapor from vaporized thermal transfer fluid that contacts the condenser during the first, two-phase immersion cooling mode;
a second single-phase mode heat removal sub-system communicating with the fluid-retaining container, the second heat removal sub-system including:
one or more pumps and fluid-removal conduits communicating with the fluid-retaining container to remove heated thermal transfer fluid from the thermal transfer fluid positioned in the fluid-retaining container during the second single-phase immersion cooling mode;
a heat exchanger for extracting thermal energy from the heated thermal transfer fluid to form cooled thermal transfer fluid;
one or more pumps and fluid-returning conduits communicating with the fluid-retaining container to return the cooled thermal transfer fluid to the fluid-retaining container; and
a controller for determining whether the multimode immersion cooling system operates only in the first two-phase mode, or whether the multimode immersion cooling system operates in the first two-phase mode and the second single-phase mode;
wherein the thermal transfer fluid includes a compound of formula (I): 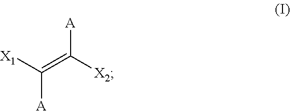
wherein X₁ and X₂ are independently selected from halogen, linear or branched partially- or fully-halogenated C₁-C₆ alkyl groups or linear or branched partially- or fully-halogenated C₁-C₆ alkenyl groups, or X₁ and X₂ are connected to form a C₅-C₆ partially- or fully-halogenated cyclic structure;
wherein A is selected from hydrogen, halogen, unhalogenated methyl group or halogenated methyl group; and
wherein the degree of fluorination of the compound is no less than 75%.

2. The multimode immersion cooling system of claim 1, wherein the boiling point of the thermal transfer fluid ranges from 50° C. to 140° C.

3. The multimode immersion cooling system of claim 1, wherein the thermal transfer fluid is non-flammable and possess no flash point.

4. The multimode immersion cooling system of claim 1, wherein the thermal transfer fluid has a dielectric constant of no higher than 2.0 at a frequency of 20-40 GHz.

5. The multimode immersion cooling system of claim 1, wherein the thermal transfer fluid has a heat of vaporization of 100-150 kJ/kg.

6. The multimode immersion cooling system of claim 1, wherein the thermal transfer fluid has a specific heat capacity of no less than 1000 J/kgK.

7. The multimode immersion cooling system of claim 1, wherein the thermal transfer fluid has a breakdown voltage of no lower than 50 kV/0.1 inch.

8. The multimode immersion cooling system of claim 1, wherein the controller circulates a cooling fluid to the condenser during the operation of the first two-phase mode heat-removal sub-system.

9. The multimode immersion cooling system of claim 1, wherein the second single-phase mode heat removal sub-system includes a first conduit for transporting heated thermal transfer fluid from the fluid-retaining container.

10. The multimode immersion cooling system of claim 9, wherein the second single-phase heat removal sub-system includes a pump for transporting the heated thermal transfer fluid in the first conduit.

11. The multimode immersion cooling system of claim 1, wherein the first conduit contacts one or more second conduits having one or more cooling fluids circulating through the one or more second conduits.

12. The multimode immersion cooling system of claim 11, wherein the cooled thermal transfer fluid is returned to the fluid-retaining container via the first conduit or via one or more second conduits.

13. The multimode immersion cooling system of claim 1, wherein the condenser of the first two-phase mode heat-removal sub-system includes one or more coils positioned in the fluid-retaining container, the one or more coils having coil cooling fluid circulating therethrough.

14. The multimode immersion cooling system of claim 13, wherein the circulating cooling fluid extracts heat from the thermal transfer fluid vapor to condense the thermal transfer fluid.

15. The multimode immersion cooling system of claim 14, wherein the circulating cooling fluid transfers the extracted heat from the thermal transfer fluid to the atmosphere by a cooling tower.
